(19) United States
(12) Patent Application Publication
(10) Pub. No.: US 2010/0177478 A1
(43) Pub. Date: Jul. 15, 2010

(54) Cooling arrangement for an equipment assembly

(76) Inventors: Lucius Chidi Akalanne, Chippenham (GB); Mark Vivian Batten, Newbury (GB)

Correspondence Address: Docket Administrator - Room 3D-201E;Alcatel-Lucent USA Inc., 600-700 Mountain Avenue, Murray Hill, NJ, 07974, US

(21) Appl. No.: 12/319,587

(22) Filed: Jan. 9, 2009

(51) Int. Cl. H05K 7/20

(52) U.S. Cl. 361/690

(57) ABSTRACT

An equipment assembly includes a core cooling slot to manage thermal effects brought about by the generation of heat from components therein. The cooling slot is positioned within the equipment assembly so that only air that is external to the equipment assembly passes through the cooling slot to provide external convection-based cooling for components in a core section inside the equipment assembly. The cooling slot also acts as a thermal barrier for redistributing heat generated by the one or more components inside the equipment assembly.

### BACKGROUND

1. Technical Field

The invention relates generally to equipment assemblies that contain computer or electronic components and the like and, more specifically, to managing thermal effects within such equipment assemblies resulting from the generation of heat by those components.

2. Discussion of the Art

This section introduces aspects that may be helpful to facilitating a better understanding of the invention. Accordingly, the statements in this section are to be read in this manner and are not to be construed as admissions about what is prior art or what is not prior art.

Equipment assemblies such as cabinets, enclosures, racks, frames, and the like for supporting or otherwise housing computer and other electronic equipment are known. Electronic components mounted within these equipment assemblies tend to generate heat that needs to be dissipated or otherwise mitigated in order to maintain proper operating conditions, to prevent damage to equipment, and so on. Thermal management has become a significant challenge as these equipment assemblies have become more densely packed with components and/or are being made smaller to occupy less footprint in facilities. Even for equipment assemblies that may not be so densely packed, it still may be important for critical components within those assemblies to not exceed maximum operating temperatures (e.g., thermal limits) in order to avoid costly repairs, system downtime, and so on. Moreover, a component may be affected not only by the heat it generates, but also by heat that gets “trapped” inside the cabinet and/or that is generated by other components that may be adjacent, in close proximity, and so on.

Overheated components do not function well over a long lifespan and thus can create problems from both an operational standpoint (e.g., damage to components, system downtime, etc.) as well as cost (e.g., maintenance, replacement, etc.). As such, it is very common for equipment assemblies to employ some type of thermal management solution, e.g., heat dissipation, reduction arrangement. Some known arrangements are heat sinks (at component level as well as on the outside equipment cabinet itself), fan-based arrangements, ducting and venting to channel warn air from inside an equipment cabinet to the outside, and so on. While there are both simple and complex arrangements in use today, there are tradeoffs and disadvantages with the different approaches. Some examples include cooling device/component costs, fan noise, additional power consumption requirements (e.g., for fans), use of otherwise available space to house the cooling devices, etc. Another drawback is that these solutions may be too “localized” in terms of cooling only certain areas within the equipment assembly, thus creating “hot spots” or “hot pockets” within the equipment assembly which may be insufficiently cooled or creating over-cooled areas.

In addition to space utilization considerations (e.g., such as a desire for smaller equipment footprint), other environmental considerations may dictate certain design choices, such as the use of airtight or substantially airtight cabinets for protection in outdoor applications. With densely packed components in an airtight equipment cabinet, managing thermal effects as well as electromagnetic radiation (EMI) can be an even greater challenge. As such, equipment assemblies for outdoor use or any use that may require some additional protection pose additional difficulties. For these types of applications, solutions that utilize open venting are not particularly beneficial because of the potential for exposure and infiltration of outside elements, e.g., environmental effects such as moisture, dust, etc. Cabinets that house telecommunications equipment, such as base stations for wireless communications networks, are one such example. Today's base stations typically include many components (e.g., power supplies, RF filters, amplifiers, etc.) housed in a relatively small sized enclosure that can generate a significant amount of heat and therefore require large volumes of air for cooling. The ability of unvented outdoor electronic cabinets to dissipate heat generated by electronic components housed within these cabinets continues to be a challenge.

### BRIEF SUMMARY

Various embodiments are set forth for dealing with thermal effects brought about by the generation of heat from components in an equipment assembly. In various embodiments, cooling is facilitated by incorporating a cooling slot within the equipment assembly to provide external convection-based cooling for the components. The cooling slot is positioned to provide cooling for components within a core section of the equipment assembly.

In accordance with a first illustrative embodiment, an equipment assembly, which is adapted to receive one or more components within a core section of the equipment assembly, has a cooling slot defined therein through which only air that is external to the equipment assembly can pass through to provide external convection-based cooling for at least the one or more components inside the core section. The cooling slot is positioned within the equipment assembly to provide a thermal barrier for redistributing heat generated by the one or more components inside the equipment assembly.

In some specific first embodiments, the cooling slot extends inwardly a predetermined distance from a top surface of the equipment assembly into the core section and the cooling slot is open at the top surface. In other specific first embodiments, the cooling slot extends inwardly from a respective surface other than a top surface of the equipment assembly into the core section and is open at that respective surface. In other specific first embodiments, the cooling slot extends laterally across substantially the entire width of the equipment assembly and is open at opposing sides of the equipment assembly. The equipment assembly may also include more than one cooling slot. The cooling slot may also be used in conjunction with (e.g., in addition to) other cooling mechanisms that may be in use within the equipment assembly, e.g., heat sinks, fans, vents, ducting, and fluid cooling mechanisms and so on.

In some specific first embodiments, the cooling slot has spaced-apart side walls extending into a core section of the equipment assembly. In some specific first embodiments, the cooling slot operates/functions as a thermal barrier between components such that thermal margins of respective components are maintained to not exceed predefined maximum operating temperatures of respective ones of the components. In another specific first embodiment, the equipment assembly is substantially airtight to substantially prevent external elements from entering inside the equipment assembly.

In accordance with a second illustrative embodiment, an apparatus is provided that includes an equipment enclosure that has a plurality of electronic components, with one or more of the plurality of electronic components located within a core section of the equipment enclosure. A cooling slot is defined within the enclosure such that only air that is external to the enclosure can flow through the cooling slot to provide external convection-based cooling for at least the one or more of the plurality of electronic components inside the core section of the enclosure. The cooling slot serves as a thermal barrier for redistributing heat generated by the plurality of electronic components inside the enclosure.

In some specific second embodiments, the cooling slot extends inwardly a predetermined distance from a top surface of the enclosure into the core section and the cooling slot is open at the top surface. In other specific second embodiments, the cooling slot extends inwardly from a respective surface other than a top surface of the enclosure into the core section and is open at that respective surface. In yet other specific second embodiments, the cooling slot extends laterally across substantially the entire width of the enclosure and is open at opposing sides of the enclosure. In some other specific second embodiments, the cooling slot is positioned in the enclosure to function as a thermal barrier between components such that thermal margins of respective components are maintained to not exceed predefined maximum operating temperatures of respective ones of the components. In another specific second embodiment, the enclosure is substantially airtight to substantially prevent elements external to the enclosure from entering into the enclosure.

In accordance with another illustrative embodiment, a method is provided for cooling an equipment cabinet that is adapted to house a plurality of components. The method provides for incorporating a cooling slot within the cabinet so that only air that is external to the cabinet can flow through the cooling slot to provide external convection-based cooling for the plurality of components inside the cabinet. The method further provides for positioning the cooling slot within a core section of the cabinet. The cooling slot acts as a thermal barrier for redistributing heat generated by the plurality of components inside the cabinet.

In accordance with another illustrative embodiment, a method is provided for operating an equipment cabinet that is adapted to house a plurality of components. The method provides for using a cooling slot to provide external convection-based cooling for the plurality of components inside the cabinet. The cooling slot is defined within a core section of the cabinet and such that only air that is external to the cabinet flows through the cooling slot. The method further provides for using the cooling slot as a thermal barrier for redistributing heat generated by the plurality of components inside the cabinet.

### BRIEF DESCRIPTION OF THE DRAWINGS

Various embodiments are shown and described in the Figures and Detailed Description of the Illustrative Embodiments. Nevertheless, the invention may be embodied in various forms and is therefore not limited only to the embodiments described and shown herein.

FIG. 1 is a side elevation view of an equipment assembly according to one illustrative embodiment of the invention;

FIG. 2 is a perspective view of the equipment assembly shown in FIG. 1;

FIG. 3 is a top elevation view of the equipment assembly shown in FIG. 1;

FIG. 4 is a cross-sectional side elevation view of a conventional equipment assembly showing thermal patterns resulting from heat generated by components therein; and

FIG. 5 is a cross-sectional side elevation view of an equipment assembly according to one illustrative embodiment of the invention showing thermal patterns resulting from heat generated by components therein.

### DETAILED DESCRIPTION OF ILLUSTRATIVE EMBODIMENTS

While the present disclosure is described, at least in some portions, in the context of telecommunications applications (e.g., a wireless base station), these examples are strictly meant to be illustrative only and not limiting in any way. In particular, the features related to the cooling arrangement described herein can be used in other non-telecommunications applications that include electronic, computer, and/or other equipment and components. Furthermore, the use of terminology such as equipment assembly, cabinet, enclosure, shelf, rack, bay, and so on, is not meant to be limiting. Rather, these terms may have equivalency and interchangeability in some contexts or, alternatively, simply illustrate the many different types of equipment housing configurations that can benefit from the cooling arrangement described herein.

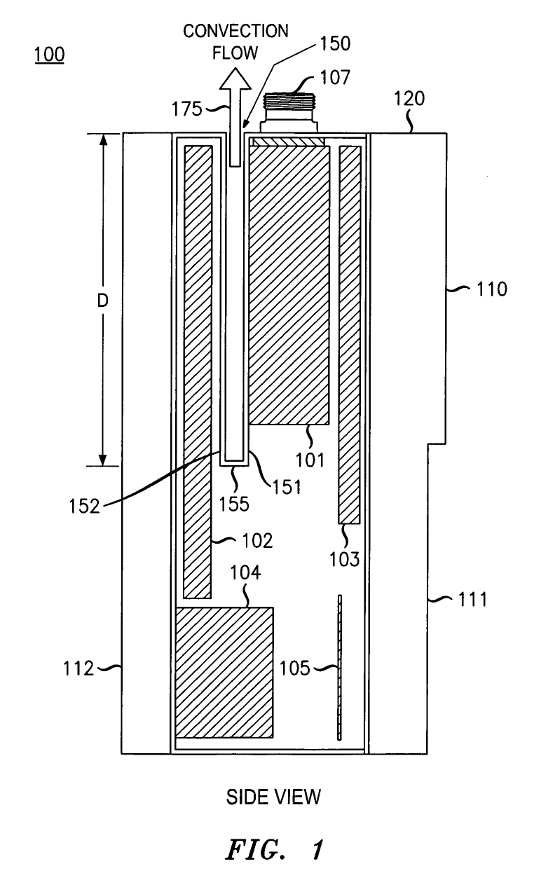

FIG. 1 shows a side view of an equipment assembly 100 (with a side panel nominally removed) according to one illustrative embodiment. Equipment assembly 100 includes a plurality of components 101, 102, 103, 104, 105 and 107, which can be electronic components configured and mounted (or otherwise housed) within equipment assembly 100 to perform certain functions, e.g., telecommunications, computer/data processing, and so on. For purposes of this illustrative embodiment, but again for exemplary purposes and not to be limiting in any way, equipment assembly 100 can be a wireless base station cabinet with an RF filter 101, a power amplifier 102, a radio unit 103, a power supply 104, an optical circuit board 105, input/output ports 107, along with other components which may of course be included as well, but which are not explicitly shown in this example for sake of brevity. In particular, equipment cabinets, such as equipment assembly 100, may typically be very densely packed with other components, cabling, mounting structures, and so on.

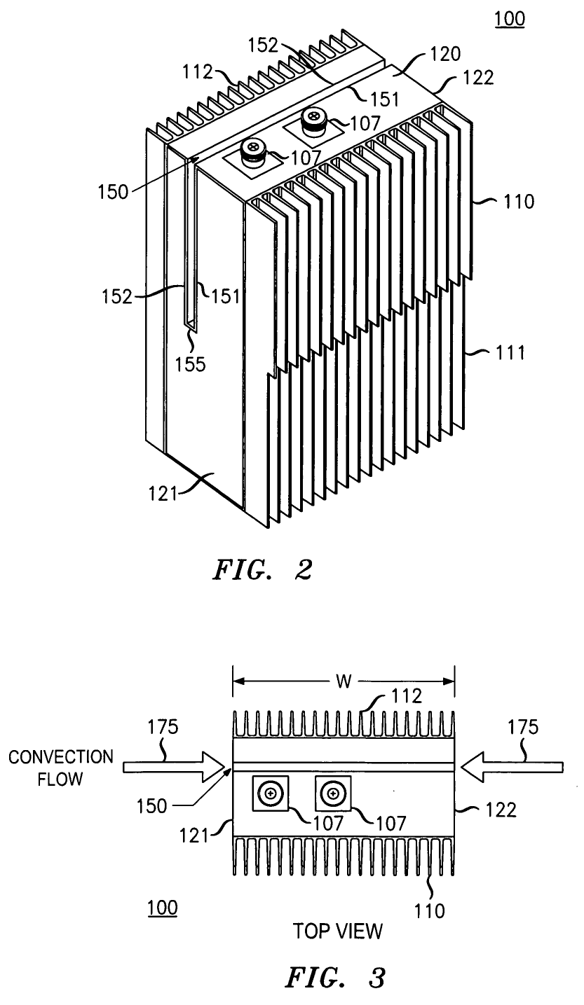

As further shown in FIG. 1, in conjunction with FIG. 2 (perspective view) and FIG. 3 (top view), equipment assembly 100 includes a cooling slot 150, defined by two spaced-apart side walls (surfaces) 151 and 152 and bottom surface 155 connecting side walls 151 and 152. Side walls 151 and 152 may be parallel, but also can be non-parallel. In this illustrative embodiment, cooling slot 150 is open at top surface 120 of equipment assembly 100 and extends downwardly a finite distance D from top surface 120 and inwardly within a core section of equipment assembly 100. Also, as shown especially in FIGS. 2 and 3, cooling slot 150 extends laterally across the width W of equipment assembly 100 from side surfaces 121 to 122. In this embodiment, cooling slot 150 is therefore also open at sides 121 and 122, which together with the opening toward top surface 120, facilitates the convection-based cooling via the circulation of air external to equipment assembly 100. Thus, in this illustrative embodiment, a core cooling slot is formed of finite depth and having a width equal to the width of the equipment assembly 100.

As will be described in further detail later, cooling slot 150 is located/positioned such that it extends into a portion or section of equipment assembly 100, which will be referred to hereinafter as a core section. It should be noted that there can be numerous modifications with respect to the positioning of cooling slot 150, e.g., different distances D from the top surface, different width W, positioned more closely toward front or back surfaces 112 and 110/111, not exactly vertical or horizontal, and so on. Cooling slot 150 can therefore be located in a number of different positions to provide cooling to a core section of equipment assembly 100 in order to help with heat dissipation on components that are located away from periphery sections of the equipment assembly and therefore typically harder to cool. For example, components more toward the periphery (e.g., edges) of equipment assembly 100, such as sidewalls 121, 122 or front surface 112, back surface 110/111, and so on can sometimes benefit from a cooling perspective by being closer to the outside of the equipment assembly 100 and thus away from the more central part of equipment assembly 100 where more heat may end up getting trapped.

Also, as shown very clearly in FIGS. 2 and 3, equipment assembly 100 may also include heat sink fins 112 (front side) and 110/111 (back side). As such, components located more toward the periphery of equipment assembly 100 may benefit from some cooling effect because of their proximity to these heat sink fins, whereas components further away from the periphery (e.g., more towards a core section or sections) may get less cooling benefit from those heat sink fins.

It should therefore be noted that one or more sections, portions, areas or regions of an equipment assembly may be deemed to be a “core” section or sections for purposes of deciding where to incorporate cooling slot 150. Placement may also depend on the particular design of that assembly in terms of where certain heat-generating components are located, where it might be feasible from a physical design standpoint to have a cooling slot 150, and so on. For example, a section of an equipment assembly may contain only one or a few components that generate high amounts of heat and therefore may benefit from a cooling slot being provided in that “core” section. As such, the use of the term “core” is not meant to be limiting to be just the center, middle, midpoint and so on. Rather, it can be anywhere within the interior of that equipment assembly. The embodiment shown in FIGS. 1-3 is a good example since it shows that cooling slot 150 is not necessarily located at the direct “middle” point (e.g., front to back).

By placing cooling slot 150 in a position such that it can extend into a more central interior section of equipment assembly 100, core cooling can be achieved through convection-based air flow principles with air that is external to equipment assembly 100. Convection-based core cooling in these areas of equipment assembly 100 thus makes it possible to cool portions that have been traditionally very difficult (or expensive) to cool, e.g., interior portions susceptible to the build up of trapped heat, congested space not so conducive to convection cooling. For example, conventional natural convection cooled enclosures are unable to extract internal waste heat trapped at the core of an enclosure because of the high thermal resistive path to the external environment. Many prior solutions have therefore been heavily dependent on the use of internal fans, which take up space, add cost, add noise, and so on.

Cooling slot 150 effectively reduces the thermal resistive path for heat to escape to the environment. So, with appropriate positioning and sizing (distance D, width W, etc.) of cooling slot 150, increased surface area can be provided for the effective collection and evacuation of internal trapped waste heat via convection air flow while also providing for more efficient use of additional space within the enclosure for other purposes. In particular, air is channelled through and across surfaces 151, 152 and 155 of cooling slot 150 to provide the convection-based cooling effect. So, the increased surface area provided by cooling slot 150 provides cooling without significantly increasing the volume of the equipment assembly 100. In fact, instead of consuming space within equipment assembly 100 for additional cooling apparatus, such as fans for example, the space can instead be more efficiently utilized to accommodate cabling, electrical inter-connects, etc. between assets internally, and so on.

In operation, as shown in FIGS. 1 and 3, arrows 175 illustrate the extra convection air flow enabled by the use of cooling slot 150. Typically, air can enter cooling slot 150 from both sides 121 and 122. Heat dissipated from some, most or all of components 101-105 would then be “convected out” and away from equipment assembly 100 via the opening at top surface 120 of cooling slot 150. It should be noted that the characteristics of the convection air flow pathways (direction, volume, etc.) may vary depending on the location of the cooling slot, the dimensions and orientation of the slot, the location and size of the open ends of the slot or slots in the equipment assembly, the physical orientation of the equipment assembly, and other factors that may influence the air flow in and through cooling slot 150. It should also be noted that side walls 151 and 152 of cooling slot 150 may either be in thermal contact with one or more components, as shown in FIG. 1 or, alternatively, may be spaced therefrom by an air gap.

The depth (distance) D of cooling slot 150 will likely be determined by the amount of space which is available within the enclosure, but can also be determined by trial and error (e.g., using thermal simulations, etc.) to produce an optimal convection air flow rate for a particular enclosure and combination of housed assets.

The outside walled surfaces of cooling slot 150 are effectively open to the outside elements (e.g., moisture, dust, etc.). However, the design of cooling slot 150 with side walls 151, 152 and bottom surface 155 for convection-based cooling as shown and described herein allows for equipment assembly 100 to remain a substantially closed element if so desired. That is, side walls 151, 152 and bottom surface 155 can be designed and constructed to not allow for any penetration of these outside elements into equipment assembly 100 since cooling slot 150 just needs to be able to facilitate and support convection-based cooling using external air that is flowing through it. Accordingly, the incorporation of cooling slot 150 in and of itself does not warrant or create any special need or requirement for additional weather proofing and the like. In fact, the design of cooling slot 150 is particularly conducive for use in an equipment assembly for outdoor (or other protected) applications, such as a wireless base station as just one of many examples, which may need to be airtight or substantially airtight to substantially prevent elements external to the equipment assembly from entering into the equipment assembly.

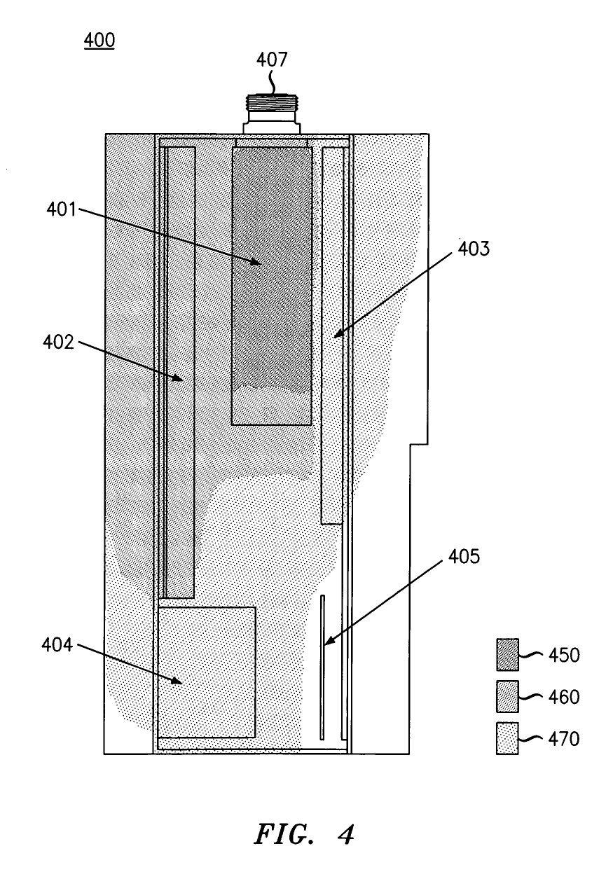

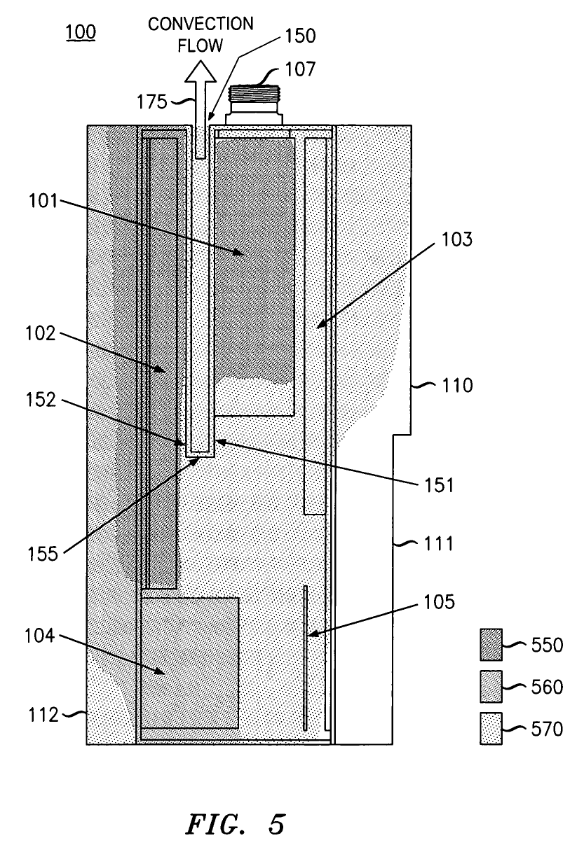

According to another aspect of the illustrative embodiment, core cooling via cooling slot 150 also controls and balances thermal margins or differentials between assets by serving as a thermal barrier to redistribute heat that is generated, trapped, and which otherwise may be transferred, shifted, and so on between and among components, which will now be described in further detail with reference to FIGS. 4 and 5.

FIG. 4 shows a conventional equipment assembly 400, which for simplicity and brevity, is shown to have similar components as equipment assembly 100 already described, but without cooling slot 150. As such, components 401-405 and 407 correspond to components 101-105 and 107 described earlier, so they will not be repeated again. Shading has been added to FIGS. 4 and 5 to show thermal patterns based on studying the computational fluid dynamics performance. Shading 450, 460 and 470 in FIG. 4 (and 550, 560, and 570 in FIG. 5) are intended to show a comparison of how heat is held within respective equipment assembly 400 (without a cooling slot 150) and equipment assembly 100 (illustrative embodiment of the invention).

As shown in FIG. 4 (without cooling slot 150), trapped heat from component 401 (shade 450) at the core of equipment assembly 400 is unable to escape because of a high thermal resistive path to the external environment. Thus, because heat cannot easily escape from a central, core portion of assembly 400, component 401 shows as being particularly hot while its surroundings are cooler. Moreover, heat generated by or around any of components 401-405 can migrate anywhere within assembly 400 and therefore have an additive effect to heat trapping within the core section of assembly 400, which may affect certain of the other components, see, e.g., shaded sections 450 and 460 in FIG. 4.

FIG. 5 shows an illustrative embodiment of the invention with cooling slot 150 and having a similar equipment configuration shown in FIGS. 1-3. As shown, the thermal pattern in and around component 101 (e.g., predominantly shading 550, 570) shows this region to be cooler than component 401 in FIG. 4 (e.g., mostly shading 450, 460 and 470) for at least two reasons. First, component 101 is adjacent and proximate to cooling slot 150 and therefore the convection air flow 175 channelling through slot 150 helps to cool and dissipate heat generated by component 101. In particular, heat generated by component 101, which would otherwise be trapped in this core section of equipment assembly 100 and/or migrate to other sections of the assembly, is now able to escape much more effectively because the thermal resistive path to the outside environment was reduced by adding the open-ended cooling slot 150, e.g., air is drawn into and flows through and across the surfaces of cooling slot 150 by convection flow 175 and thus draws heat away from component 101. Heat generated from component 102 is similarly handled and dissipated.

Secondly, core cooling is not only able to remove heat from component 101, but also provides a thermal barrier that prevents, reduces or otherwise mitigates the migration and additive transfer of heat energy from other components, e.g., heat from component 102 migrating to component 101 and effectively raising its operating temperature. By contrast, see FIG. 4 with components 401 and 402 for example. In particular, core cooling slot 150 is a barrier that effectively redistributes this heat energy within the core section of equipment assembly 100 to prevent the otherwise unimpeded transfer of heat from one component to another. This is a helpful feature because, as is well known, most electronic components have maximum operating temperatures, above which performance can degrade and, over time, could possibly lead to component failure. In turn, overall system performance can be affected in the form of downtime, costly maintenance and repairs and so on. As such, it is common in thermal management design to ensure that heat is managed appropriately so that certain thermal margins can be maintained within components, e.g., a margin or buffer between actual operating temperatures and the component's maximum recommended or allowable operating temperatures.

FIGS. 4 and 5 illustrate this point quite well in terms of how cooling slot 150 can change the effect on operating temperatures of components and the resulting effect on thermal margins by redistributing heat that would otherwise be transferred between and among components.

For example, for the configuration shown in FIG. 4 (without a cooling slot), thermal patterns around the respective components were observed in one experimental simulation to be as follows (all temperatures in Celsius):

component 401—approximately in the range of 106 degrees (shade zone 450);

component 402—approximately in the range of 96 degrees (shade zone 460); and

component 403—approximately in the range of 85 degrees (shade zone 470).

Without having a cooling slot, it was observed that heat generated by component 402 “heated up” component 401 by approximately 5 degrees. The increased temperature around component 401 then migrated to component 403 and “heated up” component 403 by approximately 2 degrees. So, the net changes in temperature differential as a result of this migration of heat between and among components can be summarized as −5 degrees for component 402, +5 degrees for component 401, and +2 degrees for component 403.

By contrast, cooling slot 150 in the illustrative embodiment shown in FIG. 5 did help to redistribute and otherwise mitigate the effects of the heat transfers that occur with the example shown in FIG. 4. For example, thermal patterns around the respective components for the illustrative embodiment of FIG. 5 were observed in one experimental simulation to be as follows (all temperatures in Celsius):

component 101—approximately in the range of 101 degrees (shade zone 550);

component 102—approximately in the range of 101 degrees (shade zone 560); and

component 103—approximately in the range of 83 degrees (shade zone 570).

So, using cooling slot 150, it was observed that component 102 heated itself up by approximately +5 degrees because it could no longer transfer its heat to component 101 since cooling slot 150 functions as a thermal barrier. Component 101 was approximately 5 degrees cooler and component 103 was about 2 degrees cooler. So, the net changes in temperature differential as a result of the redistribution of heat between and among components caused by cooling slot 150 acting/serving as a thermal barrier can be summarized as +5 degrees for component 402, −5 degrees for component 101, and −2 degrees for component 103. As a point of reference, in the wireless base station domain, a reduction (savings) in temperature of 5 degrees for some components could represent an approximately 50% improvement in predicted reliability of a component. Accordingly, adding a core cooling slot to provide convection-based cooling at the core sections of an equipment enclosure can also be an effective mechanism for balancing thermal margins.

Choosing the location and positioning of cooling slot 150 can be based on a number of factors and considerations, e.g., heat generation profiles, criticality of components, susceptibility and/or sensitivity to failure, and so on. In the present illustrative embodiments of a wireless base station, for example, RF filter 101 may be the critical component for which the thermal margin is more critical. So, the choice of where to locate cooling slot 150 can be made accordingly.

It should also be noted that other variations are contemplated within the scope of the disclosure. For example, equipment assembly may include two or more cooling slots 150 to provide core cooling into several different core sections of equipment assembly 100.

Equipment assembly 100 may also include additional components to augment heat dissipation, such as heat sink fins 110, 111 and 112 as shown in FIG. 2, which can be mounted on the front and back side of equipment assembly 100 by way of example. Other heat dissipation techniques can also be used in conjunction with cooling slot 150, e.g., fans, vents, ducting, component-level heat sinks, and fluid cooling mechanisms, to name a few.

Also, instead of extending generally downwardly from top surface 120 of equipment assembly 100, cooling slot 150 may be designed to extend horizontally or vertically in other directions extending into core sections of equipment assembly 100. For example, cooling slot 150 can open to a side surface, front or rear surface of the equipment assembly, or even to a bottom surface if ventilated (e.g., raised floor, on one or more supports, etc.).

As fully described, the flexibility available for designing, constructing and operating an equipment assembly with a cooling slot according to the principles of the invention provides a number of advantages in being able to cool equipment and components that are otherwise quite difficult to effectively cool using conventional solutions. Moreover, by using the cooling slot to provide external convection-based cooling and as a thermal barrier for redistributing heat generated by the components within an equipment assembly, an effective and cost-efficient thermal management solution can be realized which is adaptable for many different applications and types of equipment.

The present specification has been set forth with reference to illustrative embodiments, but those embodiments are not meant to be limiting in any way. Modifications and alterations will occur to others upon reading and understanding the present specification. In particular, other embodiments of the invention will be apparent to those skilled in the art upon reading the disclosure, drawings, and claims herein. It is therefore intended that the invention be construed as including all such modifications and alterations insofar as they come within the scope of the appended claims or the equivalents thereof.

1. An equipment assembly adapted to receive one or more components housed together within a core section of the equipment assembly, comprising:
a cooling slot defined within the core section of the equipment assembly through which only air that is external to the equipment assembly can pass through to provide convection-based cooling for at least the one or more components that are housed together within the equipment assembly,
wherein the cooling slot is positioned within the equipment assembly to provide a thermal barrier for redistributing heat generated by at least the one or more components housed together within the core section inside the equipment assembly.

2. The equipment assembly as recited in claim 1, wherein the cooling slot extends inwardly a predetermined distance from a top surface of the equipment assembly into the core section, and wherein the cooling slot is open at the top surface.

3. The equipment assembly as recited in claim 1, wherein the cooling slot extends inwardly from a respective surface other than a top surface of the equipment assembly into the core section and wherein the cooling slot is open at the respective surface.

4. The equipment assembly as recited in claim 1, wherein the cooling slot extends laterally across substantially the entire width of the equipment assembly and wherein the cooling slot is open at opposing sides of the equipment assembly.

5. (canceled)

6. The equipment assembly as recited in claim 1, wherein the cooling slot comprises spaced-apart side walls extending into the core section of the equipment assembly.

7. The equipment assembly as recited in claim 1, wherein the cooling slot is positioned within the equipment assembly so that at least two components are located adjacent to and in proximity of opposite spaced-apart sidewalls of the cooling slot.

8. (canceled)

9. The equipment assembly as recited in claim 1, wherein the equipment assembly houses components for a telecommunications wireless base station.

10. (canceled)

11. The equipment assembly as recited in claim 1, wherein the cooling slot is positioned to further provide the thermal barrier between components in the core section and one or more periphery sections relative to the core section within the equipment assembly.

12. The equipment assembly as recited in claim 1, wherein the cooling slot is positioned to provide the thermal barrier between components such that thermal margins of respective components are maintained to not exceed predefined maximum operating temperatures.

13. The equipment assembly as recited in claim 1, wherein the equipment assembly is substantially airtight to substantially prevent elements external to the equipment assembly from entering into the equipment assembly.

14. The equipment assembly as recited in claim 1, wherein the cooling slot is positioned to channel air external to the equipment assembly across surfaces of the cooling slot to provide the convection-based cooling.

15. An apparatus comprising:
an equipment enclosure having a plurality of electronic components housed together therein, with one or more of the plurality of electronic components being located and housed together within a core section of the equipment enclosure; and
a cooling slot defined within the core section of the enclosure such that only air that is external to the enclosure can flow through the cooling slot to provide convection-based cooling for at least the one or more of the plurality of electronic components that are housed together inside the core section of the enclosure,
wherein the cooling slot serves as a thermal barrier for redistributing heat generated by the plurality of electronic components that are housed together within the core section inside the enclosure.

16. The apparatus according to claim 15, wherein the enclosure is substantially airtight to substantially prevent elements external to the enclosure from entering into the enclosure.

17. The apparatus according to claim 15, wherein the cooling slot extends inwardly a predetermined distance from a top surface of the enclosure into the core section and wherein the cooling slot is open at the top surface.

18. The apparatus according to claim 15, wherein the cooling slot extends inwardly from a respective surface other than a top surface of the enclosure into the core section and wherein the cooling slot is open at the respective surface.

19. The apparatus according to claim 15, wherein the cooling slot extends laterally across substantially the entire width of the enclosure and wherein the cooling slot is open at opposing sides of the enclosure.

20. The apparatus according to claim 15, wherein the cooling slot is positioned to further provide the thermal barrier between components in a core section and one or more periphery sections relative to the core section within the enclosure.

21. The apparatus according to claim 15, wherein the cooling slot is positioned to provide the thermal barrier between components such that thermal margins of respective components are maintained to not exceed predefined maximum operating temperatures of respective ones of the components.

22. The apparatus according to claim 15, wherein the cooling slot is positioned to channel air external to the enclosure across surfaces of the cooling slot to provide the convection-based cooling.

23. A method of cooling an equipment cabinet adapted to house a plurality of components, comprising:
incorporating a cooling slot within a core section of the cabinet so that only air that is external to the cabinet can flow through the cooling slot to provide convection-based cooling for the plurality of components that are housed together within the core section inside the cabinet; and
positioning the cooling slot within the core section of the cabinet
such that the cooling slot acts as a thermal barrier for redistributing heat generated by the plurality of components that are housed together within the core section inside the cabinet.

24. A method of operating an equipment cabinet adapted to house a plurality of components, comprising:
using a cooling slot to provide external convection-based cooling for the plurality of components that are housed together inside the cabinet, wherein the cooling slot is defined within a core section of the cabinet and such that only air that is external to the cabinet flows through the cooling slot; and
using the cooling slot as a thermal barrier for redistributing heat generated by the plurality of components that are housed together within the core section inside the cabinet.
